(19) United States
(12) Patent Application Publication
(10) Pub. No.: US 2024/0402076 A1
(43) Pub. Date: Dec. 5, 2024

(54) OPTICAL ANALYZER AND OPTICAL ANALYSIS SYSTEM THEREFOR

(71) Applicant: Dalian Mega Crystal Biological Technology Co., Ltd., Dalian, Liaoning Province (CN)

(72) Inventors: Yi-sheng TING, New Taipei City (TW); Yu-tsung CHEN, New Taipei City (TW)

(73) Assignee: Dalian Mega Crystal Biological Technology Co., Ltd., Dalian, Liaoning Province (CN)

(21) Appl. No.: 18/697,012

(22) PCT Filed: Sep. 29, 2022
(86) PCT No.: PCT/IB2022/059268

§ 371 Date: Mar. 29, 2024

(30) Foreign Application Priority Data
Sep. 29, 2021 (TW) 110136207

(51) Int. Cl. G01N 21/31; G01N 21/25

(52) U.S. Cl. CPC G01N 21/314; G01N 21/255; G01N 2021/3181; G01N 2201/0636

(57) ABSTRACT

The invention provides an optical analyzer and an optical analysis system. The optical analyzer includes a main body having a receiving space, a rotating part, a light detection device and a driving device. light-transmitting component is provided on one side of the main body, an object-to-be-measured holding device is provided in the receiving space. The present invention achieves the measurement method of multiple repeated measurements of the object-to-be-measured through multiple light-emitting elements that respectively exhibit discontinuous illumination of on-off frequencies to go with a rotating part to drive the object-to-be-measured holding device to rotate to measure a surface of an object-to-be-measured in a non-planar or non-stationary state, to improves the signal-to-noise ratio in the spectrum of the object-to-be-measured to achieve accurate measurement results, and further provides an optical analysis system for an optical analyzer to convert the object-to-be-measured spectrum analysis results into the information required by the user.

### BACKGROUND OF THE INVENTION

### 1. Field of the Invention

The present invention relates to a technical field of an optical analyzer, and in particular to an optical analyzer capable of carrying out uniform measurements and multiple repeated measurements and an optical analysis system thereof.

### 2. Description of the Prior Art

In recent years, the development of spectroscopic technology has drawn more and more attention of the market. Through different spectral analysis technologies it is able to quickly detect the spectral characteristics of an object-to-be-measured, and verify the compositions of the object-to-be-measured by using its spectral characteristics to facilitate the subsequent processing and analysis of the object-to-be-measured. Currently spectral analysis technology has been widely used in fields such as agricultural product quality, food safety, cosmetic ingredients, clothing materials, medicine and pharmaceutical. Furthermore, through non-contact spectral analysis technology it has gradually expanded to various types of daily electrical appliances, thereby changing consumers' habits in the past.

Generally speaking, a spectral analysis instrument obtains the spectral information of the object-to-be-measured by measuring the transmitted light penetrating the object-to-be-measured or the reflected light reflected on its surface coming from the irradiation of a light source on the object-to-be-measured after meta-analysis. However, currently there are still the following shortcomings present when using a spectrum analysis instrument for measurement. For example: a user needs close contact of the surface of the object-to-be-measured when operating the spectrum analysis instrument so that the irradiation of the light source on the object-to-be-measured is sufficient to generate enough reflected light or transmitted light for the measurement of the spectrum analysis instrument. Furthermore, the light-emitting elements for use in the spectrum analysis instrument are usually installed on a flat surface. When measuring the object-to-be-measured, it is often necessary to keep the surface of the object-to-be-measured parallel with the surface on which the light-emitting elements are arranged to ensure correct measurement results. If the surface of the state or the object-to-be-measured is in a non-planar object-to-be-measured is in a non-stationary state, the measured values are prone to be incorrect to result in the misjudgment of the analysis results.

Therefore, the present invention is to explain how to effectively improve the problems while using the aforementioned traditional spectral analysis instruments by innovative hardware designs. They are still problems which developers and related researchers in related industries need to overcome and solve with continuous diligence.

### SUMMARY OF THE INVENTION

In view of these, and assisted by their rich professional knowledge and many years of practical experience, the inventors improve to invent and the objectives are to solve the problems of incorrect measured values which are caused by close contact of the traditional spectral analysis instrument only at a short distance to measure the surface of a stationary object-to-be-measured and measure a non-planar surface of an object-to-be-measured. Therefore, the present invention is proposed by the inventors to be developed with the assistance of their rich professional knowledge and many years of practical experience.

An optical analyzer includes a main body having a receiving space, a light-transmitting component provided on one side of the main body, and an object-to-be-measured holding device provided in the receiving space; a rotating part provided at the object-to-be-measured holding device; a light detection device having a solid-state light source emitter and an optical receiver, the solid-state light source emitter having a plurality of light-emitting elements of which each emits a light with at least one peak emission wavelength and at least one wavelength range, the optical receiver receiving a light emitted from the light-emitting element, and the solid-state light source emitter disposed on another side opposite to a side of the receiving space where the light-transmitting component is disposed, wherein the light is able to pass the light-transmitting component and forms an optical path along a travel pathway between the light-emitting element and the optical receiver, a distance between the light emitted from the light-emitting element and an object-to-be-measured in the object-to-be-measured holding device is at least 5 cm, the light-emitting element is a light emitting diode, a vertical-cavity surface-emitting laser or a laser diode, and the plurality of the light-emitting elements respectively exhibit discontinuous illumination of an on-off frequency, a plurality of the on-off frequencies may be the same or different from each other, or the plurality of the on-off frequencies may be partially the same or partially different; and a driving device connected to the rotating part.

In one embodiment of the present invention, the extension direction of the rotating part is defined as an X direction, the X direction is different from a Y direction and a Z direction, the Y direction and the Z direction define a YZ plane, and the X direction, the Y direction and the Z direction are perpendicular to one another, the object-to-be-measured holding device is able to rotate along the YZ plane, and an angle between a normal line of the YZ plane and the X direction is equal to 0 degrees or greater than 0 degree and less than 90 degrees.

In one embodiment of the present invention, the extension direction of the rotating part is defined as a Z direction, the Z direction is different from an X direction and a Y direction, the X direction and the Y direction define an XY plane, the X direction, the Y direction and the Z direction are perpendicular to one another, the object-to-be-measured holding device is able to rotate along the XY plane, and an angle between a normal line of the XY plane and the Z direction is equal to 0 degree or greater than 0 degree and less than 90 degrees.

In one embodiment of the present invention, the optical analyzer may include a reflective element, the reflective element is provided in the object-to-be-measured holding device, and the optical receiver may receive the light reflected from the reflective element.

In one embodiment of the present invention, the on-off frequency is between 0.05 time/second and 50000 times/second.

In one embodiment of the present invention, a time interval in the on-off frequency for turning on the light-emitting element is between 0.00001 second and 10 seconds.

In one embodiment of the present invention, a time interval in the on-off frequency for turning off the light-emitting element is between 0.00001 second and 10 seconds.

In one embodiment of the present invention, a difference between adjacent two peak emission wavelengths is between 1 nm and 80 nm.

In one embodiment of the present invention, a difference between adjacent two peak emission wavelengths is between 5 nm and 80 nm.

In one embodiment of the present invention, a full width at half maximum which each peak emission wavelength corresponds to is between 15 nm and 50 nm.

In one embodiment of the present invention, a full width at half maximum which each peak emission wavelength corresponds to is between 15 nm and 40 nm.

In one embodiment of the present invention, a plurality of the wavelength ranges of two light-emitting elements which adjacent two peak emission wavelengths correspond to partially overlap to form a continuous wavelength range which is wider than the wavelength range of each of the plurality of the light-emitting elements, or the plurality of the wavelength ranges of two light-emitting elements which adjacent two peak emission wavelengths correspond to do not overlap.

In one embodiment of the present invention, a difference between adjacent two peak emission wavelengths is greater than or equal to 0.5 nm.

In one embodiment of the present invention, a difference between adjacent two peak emission wavelengths is between 1 nm and 80 nm.

In one embodiment of the present invention, a full width at half maximum which at least a portion of the peak emission wavelength in a plurality of peak emission wavelengths corresponds to is greater than 0 nm and less than or equal to 60 nm.

In one embodiment of the present invention, the light which the light-emitting element emits has an inclination angle with respect to a surface normal line of the light-transmitting component, and the inclination angle is greater than 0 degree and less than 90 degrees.

In one embodiment of the present invention, a plurality of the light-emitting elements emit light sequentially. The aforementioned to emit light sequentially refers to a plurality of the light-emitting elements which emit the light of the same wavelength range at different positions do not emit the light at the same time; or the plurality of the light-emitting elements partially emit the light at the same time, the aforementioned to partially emit the light at the same time refers to using the plurality of the light-emitting elements so that a portion of the light-emitting elements emits at the same time and emits the light of different wavelength ranges at the same time.

The present invention, based on the main objective, further provides an optical analysis system, suitable to apply to the aforementioned optical analyzer, to include:
a first processor electrically connected to the light detection device, to the driving device, to an object-to-be-measured analysis module and to a first setting unit.

In one embodiment of the present invention, the optical analysis system further includes a first wireless communication module and the first wireless communication module is electrically connected to the first processor.

In one embodiment of the present invention, the optical analysis system further includes a first display device and the first display device is electrically connected to the first processor.

In one embodiment of the present invention, the first wireless communication module is communicatively connected to a second wireless communication module of an electronic device, and the second wireless communication module is electrically connected to a second processor.

In one embodiment of the present invention, the electronic device further includes a second setting unit, and the second setting unit is electrically connected to the second processor.

In one embodiment of the present invention, the electronic device further includes a second display device, and the second display device is electrically connected to the second processor.

Therefore, the optical analysis of the present invention achieves a measurement method of multiple repeated measurements of each piece of clothing through a plurality of light-emitting elements which each respectively exhibits discontinuous illumination of on-off frequencies to go with the rotating part to drive the object-to-be-measured holding device to rotate. In addition to being able to measure an object with a non-planar state or with a non-stationary surface, it also improves the signal-to-noise ratio in the spectrum of the object-to-be-measured after the measurement to achieve accurate measurement results. The present invention further provides an optical analysis system suitable for an optical analyzer, which can convert the obtained analysis results of the spectrum of the object-to-be-measured into the information contents required by the user.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A illustrates an overall schematic diagram of an optical analyzer according to a preferred embodiment of the present invention.

FIG. 1B illustrates a side view of an optical analyzer according to a preferred embodiment of the present invention.

FIG. 1C illustrates a tilt angle diagram of an optical analyzer according to a preferred embodiment of the present invention.

FIG. 1D illustrates an overall schematic diagram of the optical analyzer applied to a front-loading washing machine according to a preferred embodiment of the present invention.

FIG. 1E illustrates a status diagram of an optical analyzer applied to a front-loading washing machine according to a preferred embodiment of the present invention.

FIG. 2 is a radiation spectrum diagram of the light emitting diode according to the first embodiment of the present invention.

FIG. 3 is a radiation spectrum diagram of the light emitting diode according to the second embodiment of the present invention.

FIG. 4 is a radiation spectrum diagram of the light emitting diode according to the third embodiment of the present invention.

FIG. 5A illustrates a time domain signal diagram of the object-to-be-measured obtained by the light detection device of the present invention.

FIG. 5B illustrates a frequency domain signal diagram of the object-to-be-measured converted from the time domain signal of the object-to-be-measured by the light detection device of the present invention after a Fourier transform.

FIG. 5C illustrates a time domain signal diagram of the object-to-be-measured after the filtration converted from the left frequency domain signals of spectral signals of the object-to-be-measured after the filtering effect through an inverse Fourier transform by the light detection device of the present invention.

FIG. 6 is a block diagram of an optical analysis system of a preferred embodiment of the present invention.

FIG. 7 is a block diagram of electronic equipment of a preferred embodiment of the present invention.

The numeral numbers in the drawings are:
1: optical analyzer
10: main body
101: receiving space
102: light-transmitting component
103: object-to-be-measured holding device
11: rotating part
12: light detection device
120: solid-state light source emitter
121: optical receiver
13: driving device
2: optical analysis system
20: object-to-be-measured analysis module
21: first processor
22: first setting unit
23: first wireless communication module
24: first display device
3: electronic device
30: second wireless communication module
31: second processor
32: second setting unit
33: second display device
4: front-loading washing machine
L: light
A: object-to-be-measured
θ: inclination angle

### DETAILED DESCRIPTION

In order to facilitate understanding of the technical features, contents, advantages and effects achieved by the present invention, the present invention is described in detail as follows along with the accompanying drawings. The gist of the drawings used therein is only to illustrate and assist the description and may not necessarily show the true proportions and precise configurations after implementation of the present invention. Therefore, the proportions and configurations of the attached drawings should not be interpreted to limit the scope of the claims of the present invention for implementation, so it is stated in advance.

In order to make the description of the disclosure of the present invention more detailed and complete, the following provides an illustrative description of the implementation ways and specific examples of the present invention. However, they are not the only form of implementing or using the specific embodiments of the present invention.

Throughout this specification, the expressions in the singular form shall be understood to include the concept in the plural form as well, unless otherwise mentioned.

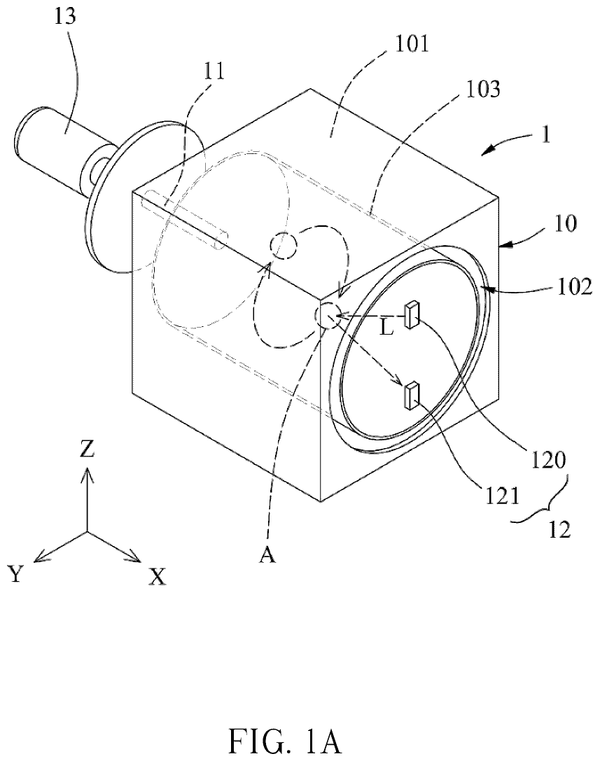

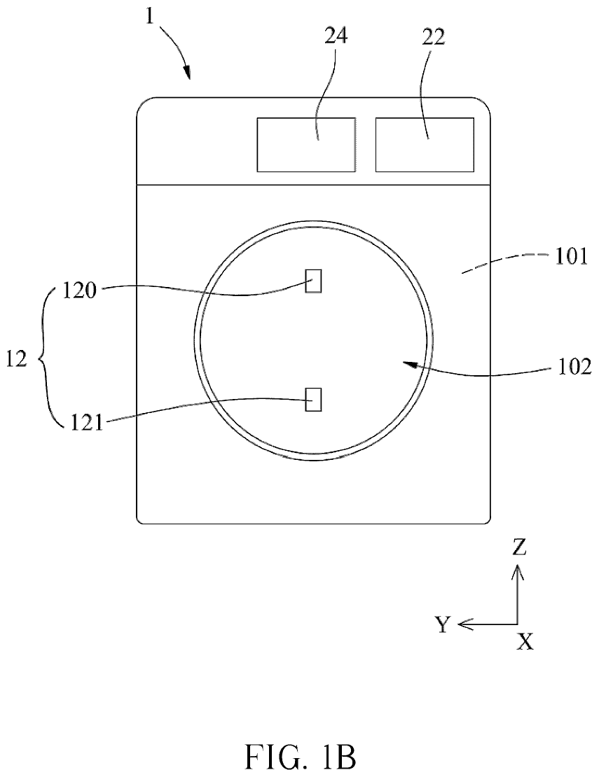

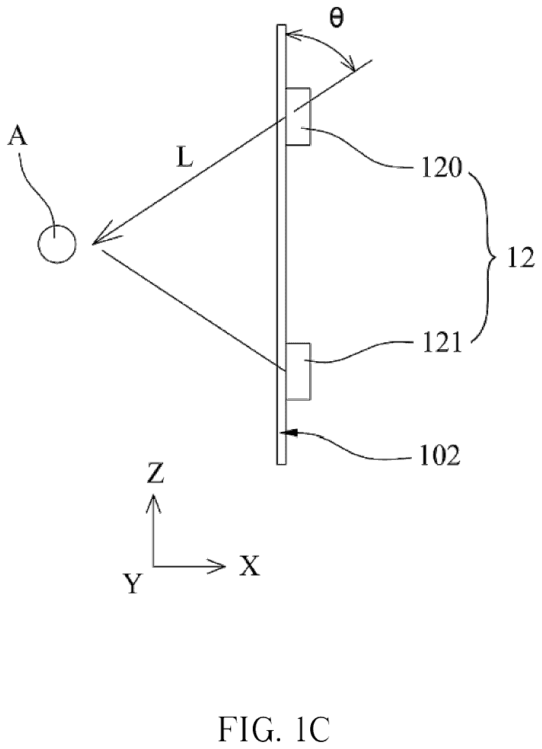

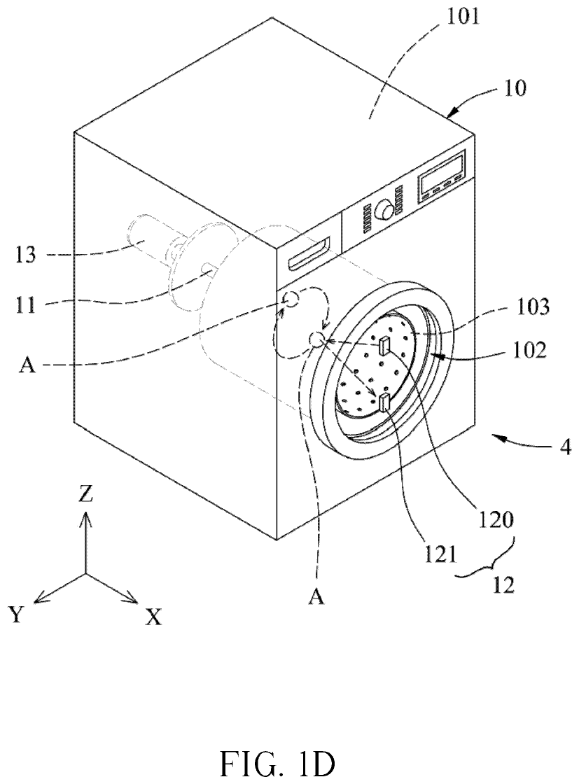

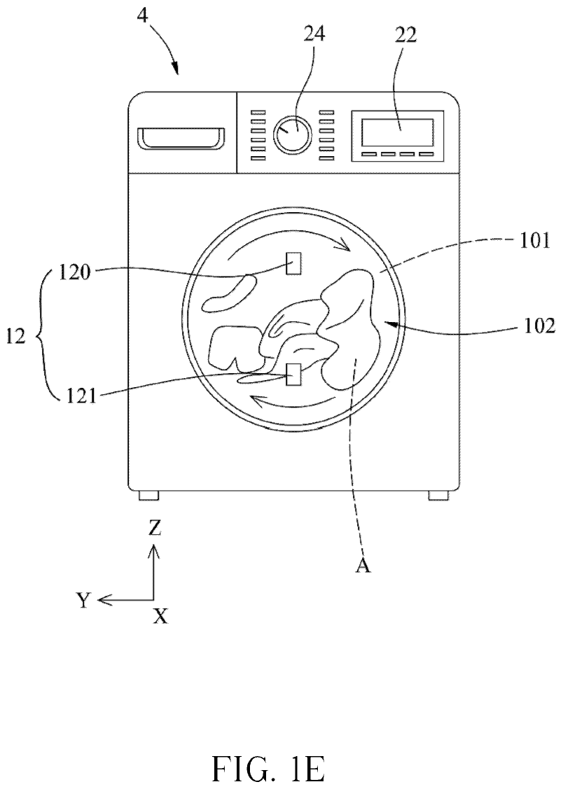

Please refer to FIG. 1A to FIG. 1E to illustrate an overall schematic diagram, a side view, a tilt angle diagram of an optical analyzer according to a preferred embodiment of the present invention, as well as an overall schematic diagram and a status diagram of the optical analyzer which is applied to a front-loading washing machine. An optical analyzer (1) includes: a main body (10), a rotating part (11), a light detection device (12) and a driving device (13). The main body (10) has a receiving space (101), a light-transmitting component (102) and an object-to-be-measured holding device (103).

The structures and operating principles of the optical analyzer of the present invention may be applied to various types of household or cooking electrical appliances, such as but not limited to, a washing machine, a dryer, an electronic pot, an oven or a microwave oven. Next, in order to enable the examiner to further understand the objectives, characteristics and desired effects achieved by the present invention, a front-loading washing machine among household electrical appliances is given below as one of the embodiments to further demonstrate the applicable ranges of the optical analyzer of the present invention, but it is not intended to limit the scope of the present invention in any way.

The main body (10) has a receiving space (101), a light-transmitting component (102) is provided on one side of the main body (10), and an object-to-be-measured holding device (103) is provided in the receiving space (101). The cross-sectional shape of the object-to-be-measured holding device (103) is circular, elliptical, polygonal, irregular, or any other shape which is able to facilitate accommodating the object-to-be-measured (A) or enable the object-to-be-measured (A) to be driven to rotate by the rotating part (11), but the present invention is not limited thereto. The light-transmitting component (102) may be fixedly provided or movably provided on one side of the main body (10).

The materials of the light-transmitting component (102) include glass, sapphire, quartz or acrylic, but the present invention is not limited thereto. For implementation, the light-transmitting component (102) may allow a light source or a light source of a specific wavelength to pass through, so that the light source may pass through the light-transmitting component (102) from the side of the main body (10) and enter the object-to-be-measured holding device (103). When it is applied to a front-loading washing machine (4), the user may view the current washing situation through the light-transmitting component (102), such as whether the clothes are tangled during the washing process, so as to handle immediately.

The size, shape or color of the main body (10) may be optionally adjusted according to the user's demands.

The optical analyzer (1) further includes a rotating part (11) and a driving device (13) connected to the rotating part (11). The rotating part (11) is linked to the object-to-be-measured holding device (103). For example: the object-to-be-measured holding device (103) may be connected to one end of the rotating part (11) in an interlocking manner according to actual needs, or to multiple rotating parts (11) at the same time to increase the operating speed. For implementation, the driving device (13) drives the rotating part (11) to rotate, and the rotating part (11) simultaneously drives the object-to-be-measured holding device (103) to rotate, and the main body (10) may also support the object-to-be-measured holding device (103) at the same time so that the object-to-be-measured holding device (103) may rotate stably, and the running speed, frequency or rotation direction of the driving device (13) may be adjusted according to properties such as the size, quantity or weight of an object-to-be-measured (A) (shown in 1E). The driving device (13) may be, for example, but not limited to a servo motor. When it is applied to a front-loading washing machine (4), the rotating part (11) first drives the object-to-be-measured holding device (103) to rotate prior to the washing of the clothes so that object-to-be-measured (A) (clothing) moves and turns up and down to achieve a measurement method of multiple repeated measurements of each piece of clothing to allow the optical analyzer of the present invention to measure and obtain the spectral data of each piece of clothing, and further obtain the material information, total content information or the proportion among different materials of this laundry load. The material information, for example: may be cotton, linen, silk, nylon, wool, rayon fiber, leather, acrylic fiber, silk, and polyester fiber . . . etc., and the total content information is the content of specific material information in the laundry load. The proportion information among different materials n may be the proportion among the total content information of the aforementioned types of clothing.

The rotating part (11) may penetrate to be disposed in the object-to-be-measured holding device (103) or respectively disposed on both sides of the object-to-be-measured holding device (103) to serve as an axis to drive the object-to-be-measured holding device (103) to rotate, or multiple rotating parts (11) may be arranged around the object-to-be-measured holding device (103). For example, the rotating part (11) may be a gear to engage the gear of the object-to-be-measured holding device (103) to rotate. A plurality of the rotating parts (11) may also respectively rotate individually or not rotate. With the cooperation among a plurality of the rotating parts (11) to jointly drive the object-to-be-measured holding device (103) to rotate, or the plurality of rotating parts (11) may also include chains, crawlers, belts, or other items which can drive the object-to-be-measured holding device (103).

The light detection device (12) may detect an object-to-be-measured (A) and generate a spectrum chart of a corresponding absorption spectrum, transmission spectrum or reflection spectrum, and through the analysis of the spectral chart the related information of the object-to-be-measured (A) is known. When applied to a front-loading washing machine (4), various types of information of the laundry load prior to washing are pre-analyzed through the optical analyzer before the clothes are washed, such as: the material information of the laundry load, the total content information of the laundry load or the proportion information among different materials of the laundry load to facilitate the subsequent front-loading washing machine to determine the required washing time, the water volume for washing, the content of additives such as laundry detergents or softeners or the number of washes, thereby generating a better washing mode, such as a washing mode which is less harmful to the clothes, a quick washing mode which cleans in shorter time or a full washing mode which fully cleans clothes, etc.

Please refer to FIG. 1D again. The light detection device (12) has a solid-state light source emitter (120) and an optical receiver (121). The solid-state light source emitter (120) may be, for example, a light emitting diode (LED), laser diode (LD). The solid-state light source emitter (120) has a light source, and the optical receiver (121) receives a light (L) emitted from the light source. The light-transmitting component (102) may allow the light (L) to pass through. In one embodiment of the present invention, the solid-state light source emitter (120) is disposed on another side of the receiving space (101) relative to the side where the light-transmitting component (102) is disposed. The solid-state light source emitter (120) includes a light source. The light source may be, for example but not limited to, a single light source group or include a plurality of sub-light source groups. When the light source includes a plurality of sub-light source groups, each one of the sub-light source groups includes a plurality of light-emitting elements which each one emits a light with at least one peak emission wavelength and with at least one wavelength range. A plurality of the sub-light source groups and/or a plurality of the light-emitting elements are electrically connected to a circuit board of the light source. A plurality of the sub-light source groups are irregularly arranged or regularly arranged.

Through the light-emitting element of a light emitting diode or a laser diode, a distance between the light (L) emitted by the light-emitting element and an object-to-be-measured (A) in the object-to-be-measured holding device (103) may be up to at least 5 cm to solve the problem, i.e., the object-to-be-measured can only be spectrally analyzed by close contact at a short distance after a traditional optical analyzer carries out optical splitting by use mixed light. Through the optical analyzer using a light emitting diode or a laser diode of the present invention, it enables the light detection device (12) to carry out the spectral analysis on the object-to-be-measured over a long distance. When applied to a front-loading washing machine (4), the user may preset the distance between the light (L) emitted by the light-emitting element and an object-to-be-measured (A) in the object-to-be-measured holding device (103) to be from 5 cm to 30 cm according to the distribution of turning and moving up and down of the object-to-be-measured (A) (clothing) in the object-to-be-measured holding device (103) prior to washing the clothes, so as to achieve the efficacy of multiple and effective measurements of the spectral data of each clothing, but the distance is not limited thereto. The distance can be adjusted accordingly to go with different sizes of the front-loading washing machine (4) or with different locations where the light-emitting element is arranged.

In one embodiment of the present invention, the optical analyzer (1) may further include a reflective element. The reflective element is disposed in the object-to-be-measured holding device (103). The optical receiver (121) receives the light (L) reflected from the reflective element. The solid-state light source emitter (120) has a light source, and the optical receiver (121) receives a light (L) reflected from the reflective element. The travel path of the light (L) between the light source, the reflective element and the optical receiver (121) forms an optical path. The reflective element can be a white board, a metal plate, a reflective plate, a reflective mirror, a reflective coating or any object with reflective capabilities.

The optical receiver (121) receives a light (L) emitted from the light source, and the light (L) may pass through the light-transmitting component (102) and the travel path between the light-emitting element and the optical receiver (121) forms an optical path. The optical receiver (121) may be, for example, a photodetector, a photo diode, an organic photo diode, a photomultiplier, a photoconducting detector, a Si bolometer, an one-dimensional or multi-dimensional photo diode array, an one-dimensional or multi-dimensional CCD (Charge Coupled Device) array, an one-dimensional or multi-dimensional CMOS (Complementary Metal-Oxide-Semiconductor) array, an image sensor (19), a camera, a spectrometer or a hyperspectral camera. An object-to-be-measured (A) is placed on the path of the light path which penetrates the object-to-be-measured (A) or forms diffuse reflection light on the surface of the object-to-be-measured (A); or, the light path finally forms diffuse reflection light after passing through and penetrating one or more times on the surface of and in the object-to-be-measured (A). The optical receiver (121) converts the aforementioned diffuse reflection light into an image signal, into a spectral signal of the object-to-be-measured, into a voltage signal and/or a current signal, and transmits the image signal, the spectral signal of the object-to-be-measured, the voltage signal and/or the current signal to a first processor (21). An image drawing and/or an object-to-be-measured spectral drawing is formed after the first processor (21) converts the image signal and/or the spectral signal of the object-to-be-measured. In other words, the optical receiver (121) includes an image extractor and/or a light detector which are electrically connected. For example, the image extractor may be a camera, a CCD or a CMOS to convert the light (L) into the image signal. The light detector may be a spectrometer to convert the light (L) into the spectral signal of the object-to-be-measured. For another example, the aforementioned photo diode can convert the light (L) into the voltage signal or into the current signal.

As shown in FIG. 1E, it illustrates an overall schematic diagram of an object-to-be-measured container device according to a preferred embodiment of the present invention. The extension direction of the rotating part (11) is defined as an X direction, the X direction is different from a Y direction and a Z direction, the Y direction and the Z direction together define an YZ plane, and the X direction, the Y direction and the Z directions are perpendicular to one another. For implementation, the angle between the normal line of the YZ plane and the X direction is equal to 0 degree or greater than 0 degree and less than 90 degrees. The object-to-be-measured holding device (103) may rotate along the YZ plane, so that the object-to-be-measured (A) accommodated in the object-to-be-measured holding device (103) can move and turn up and down to achieve a uniform mixing effect. When applied to a front-loading washing machine (4), the optical analyzer of the present invention may measure and obtain the spectral data of each piece of clothing.

The extension direction of the rotating part (11) is defined as a Z direction. The Z direction is different from an X direction and from a Y direction. The X direction and the Y direction together define an XY plane, and the X direction, the Y direction and the Z directions are perpendicular to one another. The object-to-be-measured holding device (103) may rotate along the XY plane, and the angle between the normal line of the XY plane and the Z direction is equal to 0 degree or greater than 0 degree and less than 90 degree. Through the aforementioned rotation method, the optical analyzer of the present invention may be applied to various types of household or cooking electrical appliances, such as but not limited to, a washing machine, a dryer, an electronic pot, an oven or a microwave oven etc. for implementation,

As shown in FIGS. 1A and 1n FIG. 1B, the object-to-be-measured holding device (103) may rotate along the YZ plane, and the angle between the normal line of the YZ plane and the X direction is equal to 0 degree or greater than 0 degree and less than 90 degrees. For example, in one embodiment of the present invention, the object-to-be-measured holding device (103) may accommodate an object-to-be-measured (A), and the object-to-be-measured (A) may occupy a volume of the receiving space (101) at a certain proportion, so that the object-to-be-measured (A) accommodated in the receiving space (101) may turn and move up and down to achieve a result of uniformly mixing within a short period of time when the object-to-be-measured holding device (103) rotates along the YZ plane.

Please refer to FIG. 1E again. The solid-state light source emitter (120) is disposed on another side of the receiving space (101) relative to the side where the light-transmitting component (102) is disposed. The light detection device (12) can adjust the position of the light detection device (12) adjacent to the light-transmitting component (102) according to the rotation direction of the object-to-be-measured holding device (103). For example, in an embodiment of the present invention, the object-to-be-measured holding device (103) is divided into an upper left area, a lower left area, an upper right area and a lower right area after the first direction line and the second direction line cross. When the object-to-be-measured holding device (103) rotates clockwise along the YZ plane, the distribution of the object-to-be-measured (A) is in the lower left area or in the lower right area. Therefore, the light detection device (12) may be adjusted to be in the lower left area or in the lower right area, so that the light detection device (12) obtain a better spectrum detecting the may when object-to-be-measured (A) to facilitate the subsequent analysis of the spectrum.

In an embodiment of the present invention, the main body (10) further includes a main body cover and an opening. The opening connects the receiving space (101) and the object-to-be-measured holding device (103). The main body cover movably seals the opening. For implementation, the user can place different objects-to-be-measured (A) in the object-to-be-measured holding device (103) through the opening, and then the main body cover can be placed on the opening, or the main body cover is pivotally provided at the object-to-be-measured holding device (103) through a pivot so that the main body cover can pivotally swing to adjust the angle. Finally, the main body cover seals the opening to prevent the objects-to-be-measured (A) from falling out when the object-to-be-measured holding device (103) rotates.

At least one heat dissipation hole is provided on one side of the main body (10) or the main body (10) is further provided with a heat dissipation unit. The heat dissipation unit may be, for example but not limited to, an active heat dissipation fan or a passive heat dissipation heat sink, a heat-conductive sheet, thermal paste or thermal glue. When the optical analyzer (1) is operating and the heat dissipation unit which is used is a fan, external air can be driven into the interior of the casing, and the heat generated during the operation of the optical analyzer (1) can be conducted outward through the heat dissipation holes along with the air flow to provide a heat dissipation effect.

As shown in FIG. 1C, in one embodiment of the present invention, the light (L) emitted by the light-emitting element has an inclination angle (θ) with the surface normal line of the light-transmitting component (102). The inclination angle (θ) is greater than 0 degree and less than 90 degrees. For implementation, the light source which is used is a simple light source and different from the mixed light which is used in the traditional optical analyzer to measure the object-to-be-measured after light-splitting since the light detection device (12) uses a light emitting diode or a laser diode as the light source of the optical analyzer of the present invention. Therefore, the simple light source used in the present invention has the characteristics of high light source intensity and can not only penetrate glass or plastic with an average thickness of 5 to 10 millimeters (mm) but also there is no problem of light source dispersion at different tilt angles (θ) to achieve accurate measurement results.

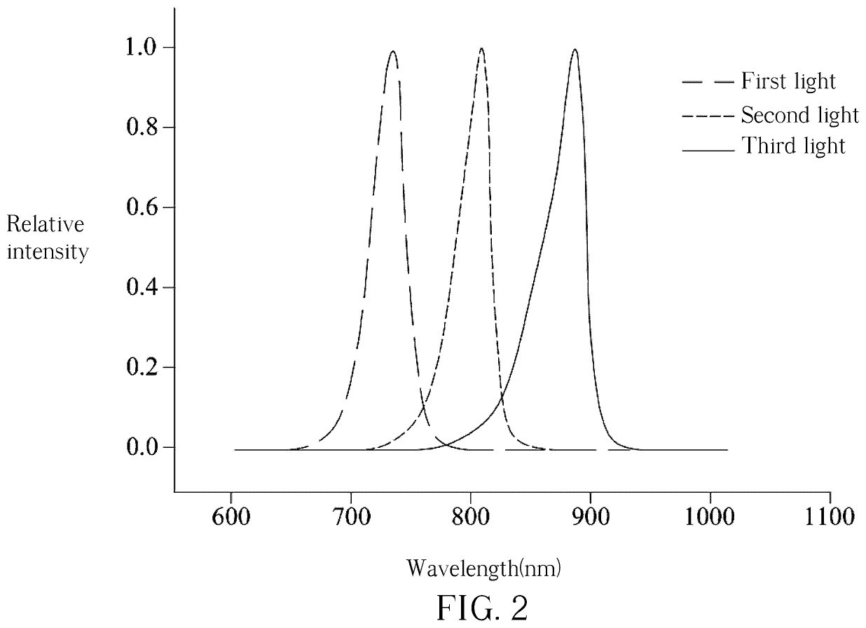

Please refer to FIG. 2 together. A plurality of wavelength ranges of two photo diodes which adjacent two peak emission wavelengths correspond to partially overlap to form a continuous wavelength range which is wider than the wavelength range of each of the plurality of the photo diodes. The continuous wavelength range is between 180 nm and 2500 nm. In FIG. 2, there are three peak emission wavelengths and the corresponding wavelength ranges, i.e. the first wavelength range which a first peak emission wavelength (734 nm) of a first light corresponds to, a second wavelength range which a second peak wavelength (810 nm) of a second light corresponds to and the third wavelength range which a third peak emission wavelength (882 nm) of a third light corresponds to. The first peak emission wavelength and the second peak emission wavelength are adjacent two peak emission wavelengths. Similarly, the second peak emission wavelength and the third peak emission wavelength are also adjacent two peak emission wavelengths. The first wavelength range which the first peak emission wavelength corresponds to is between 660 nm and 780 nm, and the second wavelength range which the second peak emission wavelength of the second light corresponds to is between 710 nm and 850 nm. The first wavelength range and the second wavelength range partially overlap between 710 nm and 780 nm, so the first wavelength range and the second wavelength range together form the continuous wavelength range between 660 nm and 850 nm. Similarly, the second wavelength range which the second peak emission wavelength corresponds to is between 710 nm and 850 nm, and the third wavelength range which the third peak emission wavelength of the third light corresponds to is between 780 nm and 940 nm, and the second wavelength range and the third wavelength range partially overlap between 780 nm and 850 nm, so the second wavelength range and the third wavelength range together form the continuous wavelength range between 710 nm and 940 nm. In the present invention, the overlapping portions of a plurality of aforementioned wavelength ranges of the adjacent two light emitting diodes which adjacent two peak emission wavelengths correspond to should be as small as possible. Of course, it is possible that a plurality of the aforementioned wavelength ranges of two photo diodes which adjacent two emission peak wavelengths correspond to may not overlap, either. This will be explained later.

The difference between adjacent two peak emission wavelengths is greater than or equal to 0.5 nm, preferably between 1 nm and 80 nm, and more preferably between 5 nm and 80 nm. In FIG. 2, the difference between the adjacent first peak emission wavelength (734 nm) and the second peak emission wavelength (810 nm) is 76 nm, and the difference between the adjacent second peak emission wavelength (810 nm) and the third peak emission wavelength (882 nm) is 72 nm. Unless otherwise specified, the limits of the numerical ranges described in the present invention and in the patent scope always include end values. For example, the difference between the adjacent two peak emission wavelengths as mentioned above is between 5 nm and 80 nm, which refers to greater than or equal to 5 nm and to less than or equal to 80 nm.

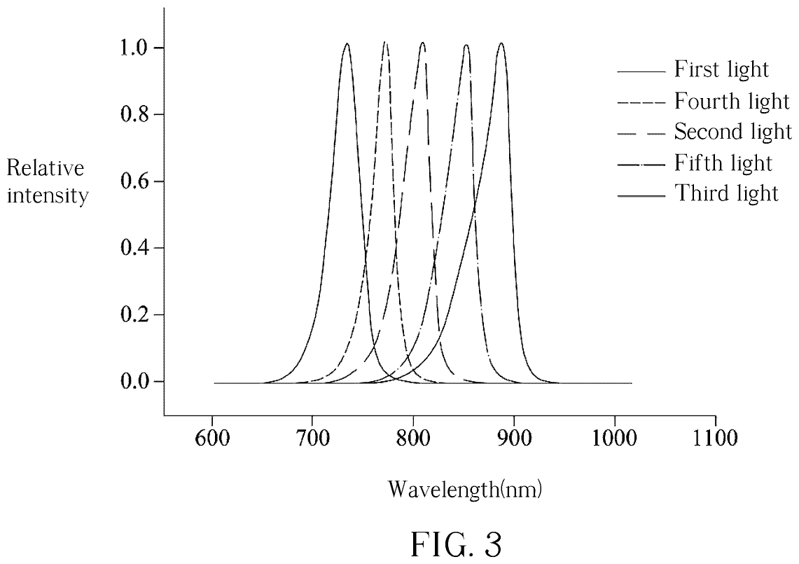

Please refer to the second embodiment of FIG. 3 together. The second embodiment is a derivative embodiment of the first embodiment, so no description is given to the similar parts between the second embodiment and the first embodiment. The difference between the second embodiment and the first embodiment resides in that the light source of the second embodiment includes five photo diodes which respectively a first photo diode emitting having, a fourth photo diode emitting a fourth light having a fourth wavelength range, a second photo diode, a fifth photo diode emitting a fifth light having a fifth wavelength range, and a third photo diode. The fourth light has a fourth peak emission wavelength (772 nm) within the fourth wavelength range. The fifth light has a fifth peak emission wavelength (854 nm) within the fifth wavelength range. In FIG. 3, the peak emission wavelengths in ascending order are the first peak emission wavelength (734 nm), the fourth peak emission wavelength (772 nm), the second peak emission wavelength (810 nm), the fifth peak emission wavelength (854 nm) and the third peak emission wavelength (882 nm). The difference between the adjacent first peak emission wavelength (734 nm) and the fourth peak emission wavelength (772 nm) is 38 nm, the difference between the adjacent fourth peak emission wavelength (772 nm) and the second peak emission wavelength (810 nm) is 38 nm, the difference between the adjacent second peak emission wavelength (810 nm) and the fifth peak emission wavelength (854 nm) is 44 nm, and the difference between the adjacent fifth peak emission wavelength (854 nm) and the third peak emission wavelength (882 nm) is 28 nm.

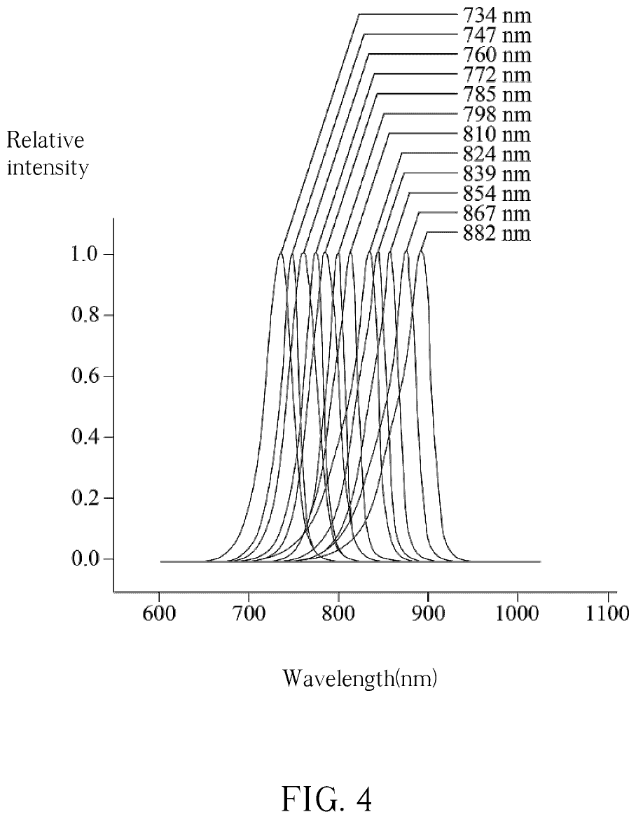

Please refer to the third embodiment of FIG. 4 together. The third embodiment is a derivative embodiment of the first embodiment and of the second embodiment, so no description is given to the similar parts between the third embodiment and the first embodiment/the second embodiment. The difference between the third embodiment and the first embodiment resides in that the light source of the third embodiment includes 12 photo diodes. In FIG. 4, the peak emission wavelengths of the 12 photo diodes in ascending order are 734 nm (the first peak emission wavelength), 747 nm, 760 nm, 772 nm (the fourth peak emission wavelength), 785 nm, 798 nm, 810 nm (the second peak emission wavelength), 824 nm, 839 nm, 854 nm (the fifth peak emission wavelength), 867 nm and 882 nm (the third peak emission wavelength). Among the peak emission wavelengths of the 12 photo diodes, the differences between adjacent two peak emission wavelengths are 13 nm, 13 nm, 12 nm, 13 nm, 13 nm, 12 nm, 14 nm, 15 nm, 15 nm, 13 nm and 15 nm in order. If the light-emitting element in the first, in the second and in the third embodiments is changed to a laser diode, the difference between adjacent two peak emission wavelengths may be greater than or equal to 0.5 nm, such as 1 nm.

A full width at half maximum which at least a portion of the peak emission wavelength in a plurality of peak emission wavelengths corresponds to is greater than 0 nm and less than or equal to 60 nm. Preferably, the full width at half maximum which each peak emission wavelength corresponds to is greater than 0 nm and less than or equal to 60 nm. For example, in the aforementioned first embodiment, second embodiment and third embodiment, the peak emission wavelengths in ascending order are 734 nm (the first peak emission wavelength), 747 nm, 760 nm, 772 nm (the fourth peak emission wavelength), 785 nm, 798 nm, 810 nm (the second peak emission wavelength), 824 nm, 839 nm, 854 nm (the fifth peak emission wavelength), 867 nm and 882 nm (the third peak emission wavelength). The full width at half maximum which the first peak emission wavelength of the first light corresponding to, the full width at half maximum which the second peak emission wavelength of the second light corresponding to, the full width at half maximum which the third peak emission wavelength of the third light corresponding to, the full width at half maximum which the fourth peak emission wavelength of the fourth light corresponding to, and the full width at half maximum which the fifth peak emission wavelength of the fifth light corresponding to is greater than 0 nm and less than or equal to 60 nm, preferably between 15 nm and 50 nm, and more preferably between 15 nm and 40 nm. The full width at half maximum (FIG. 4) which other unspecified peak emission wavelengths 747 nm, 760 nm, 785 nm, 798 nm, 824 nm, 839 nm and 867 nm correspond to is also greater than 0 nm and less than or equal to 60 nm, preferably between 15 nm and 50 nm, and more preferably between 15 nm and 40 nm. During the experimental operations of the present invention, the full width at half maximum which the peak emission wavelengths in the aforementioned first embodiment, second embodiment and third embodiment correspond to is 55 nm. If the light-emitting element is a laser diode, the full width at half maximum which each the peak emission wavelength correspond to is greater than 0 nm and less than or equal to 60 nm, for example, 1 nm.

A plurality of the wavelength ranges of two photo diodes which adjacent two peak emission wavelengths correspond to may not overlap. For example, if the full width at half maximum which each the peak emission wavelength in the first embodiment, the second embodiment and the third embodiment corresponds to is 15 nm, the width of the wavelength range which each the peak emission wavelength corresponds to (that is, the difference between the maximum value and the minimum value of the wavelength ranges) is 40 nm. The difference between adjacent two peak emission wavelengths is 80 nm. For another example, if the light-emitting element is a laser diode, the full width at half maximum which each the peak emission wavelength corresponds to is 1 nm, the width of the wavelength range is 4 nm, and the difference between adjacent two peak emission wavelengths is 5 nm, then a plurality of the wavelength ranges of two light-emitting elements (laser diodes) which adjacent two peak emission wavelengths correspond to do not overlap.

Preferably, to operate an imaging device to carry out the detection of the object-to-be-measured (A) to generate the spectrum drawing of the object-to-be-measured in the first embodiment, the second embodiment and the third embodiment, the imaging device is a mobile phone or a tablet computer. As mentioned above, the solid-state light source emitter (120) can separately control to cause a plurality of photo diodes to respectively exhibit discontinuous illumination of light of an on-off frequency. A plurality of the on-off frequencies may be the same or different from each other, or a plurality of the on-off frequencies may be partially the same or partially different. The aforementioned on-off frequency is between 0.05 time/second and 50000 times/second. The time interval for turning on (light on) the photo diode in the on-off frequency is between 0.00001 second and 10 seconds, and the time interval for turning off (light off) the photo diode in the on-off frequency is between 0.00001 seconds and 10 seconds. The period of the on-off frequency refers to the sum of one consecutive time interval to turn on (light on) the photo diode and time interval to turn off (light off) the photo diode, the period of the on-off frequency is the reciprocal of the on-off frequency. In other words, the period of the on-off frequency can be understood as the sum of continuous turning on−the time interval to turn on and immediately continuous turning off−the time interval to turn off a plurality of light emitting diodes without interruption. The time interval to turn on is between 0.00001 second and 10 seconds. The time interval to turn off is between 0.00001 second and 10 seconds. Preferably, the on-off frequency is between 0.5 time/second and 50,000 times/second; more preferably, the on-off frequency is between 5 times/second and 50,000 times/second. A plurality of photo diodes exhibiting discontinuous illuminating state can greatly reduce the influence of the heat energy of the light emitted by the photo diodes on the object-to-be-measured (A) to avoid qualitative changes of the object-to-be-measured (A) which contains organisms. Therefore, it is particularly suitable for an object-to-be-measured (A) which is sensitive to heat energy, and particularly suitable for the light emitted by the photo diode in the wavelength range of near-infrared light. Through the aforementioned plurality of light-emitting elements which respectively exhibit discontinuous illumination of an on-off frequency to go with the rotating part (11) to drive the object-to-be-measured holding device (103) to rotate to achieve a measurement method of multiple repeated measurements of each piece of clothing, so that the spectral analysis results are close to that of the high-resolution results by using a traditional tungsten halogen lamp spectrometer, and further it also simultaneously improves the signal-to-noise ratio in the spectrum of the object-to-be-measured after detection to be able to achieve accurate measurement results, so that the optical analyzer of the present invention can measure an object-to-be-measured whose surface is in a non-planar state or in a non-stationary state. When applied to a front-loading washing machine (4), the optical analyzer of the present invention can measure and obtain spectral data of each piece of clothing, thereby obtaining results of more accurate material information, of total content information, or of the proportion among different materials of the clothing to facilitate the front-loading washing machine to subsequently determine the required washing time, the water volume for washing, the content of additives such as laundry detergents or softeners, or the number of washes.

Specifically speaking, synchronous operation and non-synchronous operation of the image extractor and the photodetector of the aforementioned light-emitting element and the optical receiver (121) may also refer to that: the image extractor and the photodetector operate at an operating frequency for discontinuous operation, the on-off frequency of the light-emitting element is the same as the operating frequency of the image extractor and of the photodetector of the optical receiver (121).

The present invention in addition provides an imaging method by using the light detection device (12) for operation. The imaging method lets a plurality of light-emitting elements in a plurality of the sub-light source groups emit light sequentially, emit light partially simultaneously, or all emit light at the same time. The aforementioned sequential emission means that a plurality of the light-emitting elements which emit a light of the same wavelength range in a plurality of the sub-light source groups at different positions on the circuit board do not emit the light at the same time, and the image extractor of the optical receiver (121) and the photodetector is turned on to operate when any of the light-emitting elements emits the light, and is turned off to stop operating when any of the light-emitting elements does not emit light. In other words, the light-emitting element simultaneously operate or does not operate with the image extractor of the optical receiver (121) and the photodetector to receive and to respectively transmit the image signals to which the light is converted after being reflected and/or scattered to the calculator during operation, and converts the light after being reflected and/or scattered into the spectral signals of the object-to-be-measured to be transmitted to the calculator. The calculator calculates the image signals of the aforementioned four positions and the spectral signals of the object-to-be-measured by using a uniform algorithm to obtain accurate imaging data. For example, there are a total of four first light emitting diodes located at four different positions on the circuit board in the four sub-light source groups. The first light emitting diode at the first position is turned on (light on) first and then is turned off (light off); the image extractor and the light detector respectively transmit the image signals and the spectral signals of the object-to-be-measured at the first position to the calculator; then the first light emitting diode at the second position is turned on first and then turned off. The image extractor and the light detector respectively transmit the image signals and the spectral signals of the object-to-be-measured at the second position to the calculator. Then the first light emitting diode at the third position is turned on first and then turned off, and the image extractor and the light detector respectively transmit the image signals and the spectral signals of the object-to-be-measured at the third position to the calculator; at least, the first light emitting diode at the fourth position is turned on first and then turned off, and the image extractor and the light detector respectively transmits the image signals and the spectral signals of the object-to-be-measured at the fourth position to the calculator. In the imaging method the calculator calculates the image signals and the spectral signal of the object-to-be-measured at the four positions by using the uniform algorithm to obtain accurate imaging data to complete the sequential light-emitting of the four first light emitting diodes. For example, the uniform algorithm method is to add up the image signals at four positions then divide by four, and to respectively add up the spectral signals of the object-to-be-measured at four positions then divide by four. After the four first light emitting diodes all have emitted light, then the four second light emitting diodes are turned on and off according to the way of the aforementioned four first light emitting diodes to complete the sequential light-emitting of the four second light emitting diodes. Finally, the sequential light-emitting of the four third light emitting diodes is completed. To explain in particular, the present invention may of course selectively let the light-emitting element at a specific position emit light again to repeatedly obtain the image signals and the spectral signals of the object-to-be-measured, for example, when it is necessary to verify whether the image signals and the spectral signals of the object-to-be-measured with the same wavelength range at the same position of previous time are correct.

The aforementioned partially emitting light simultaneously refers to that some in a plurality of light-emitting elements in a plurality of sub-light source groups emit light simultaneously and simultaneously emit light which is different from the wavelength ranges based on the light of different wavelength ranges which has differences in response to the object-to-be-measured (A). The obtained image signals and spectral signals of the object-to-be-measured may represent the resulted physical meaning or chemical meaning when the object-to-be-measured (A) is under the irradiation of light of a plurality of different wavelength ranges at the same time. This is obviously different from the aforementioned method of emitting light sequentially. The aforementioned method of emitting light sequentially cannot observe the simultaneous influences of a plurality of different wavelength ranges on the object-to-be-measured (A). Another advantage of the aforementioned partially emitting light simultaneously is that the time for the detection of object-to-be-measured (A) by the aforementioned partially emitting light simultaneously can be reduced compared with the aforementioned emitting light sequentially.

By using the light-emitting elements at different positions to emit light sequentially or partially simultaneously, in particular there are different components in a plurality of regions of the object-to-be-measured (A), the imaging method uses the calculator to calculate the image signals at the aforementioned a plurality of locations and the spectral signals of the object-to-be-measured by using the uniform algorithm to obtain average imaging data, so it is beneficial to go a quick overall evaluation of the object-to-be-measured (A) even if there are the same compositions in a plurality of regions of the object-to-be-measured (A). However, if the surface of the object-to-be-measured (A) cannot remain parallel to the light source, then the distances between each of the light-emitting element and the object-to-be-measured (A) are different, which would lead to the distortion of the image signals and of the spectral signals of the object-to-be-measured which are generated by each light-emitting element. In this case, by using the light-emitting elements at different positions to emit light sequentially or partially simultaneously, the imaging method may use the calculator to calculate the image signals at the aforementioned plurality of positions and the spectral signals of the object-to-be-measured by using the uniform algorithm to obtain the average imaging data so it is beneficial to go a quick overall evaluation of the object-to-be-measured (A).

The present invention uses light-emitting elements at different positions to emit light sequentially or partially simultaneously to carry out a calculation by a uniform algorithm so the accurate imaging data can be obtained.

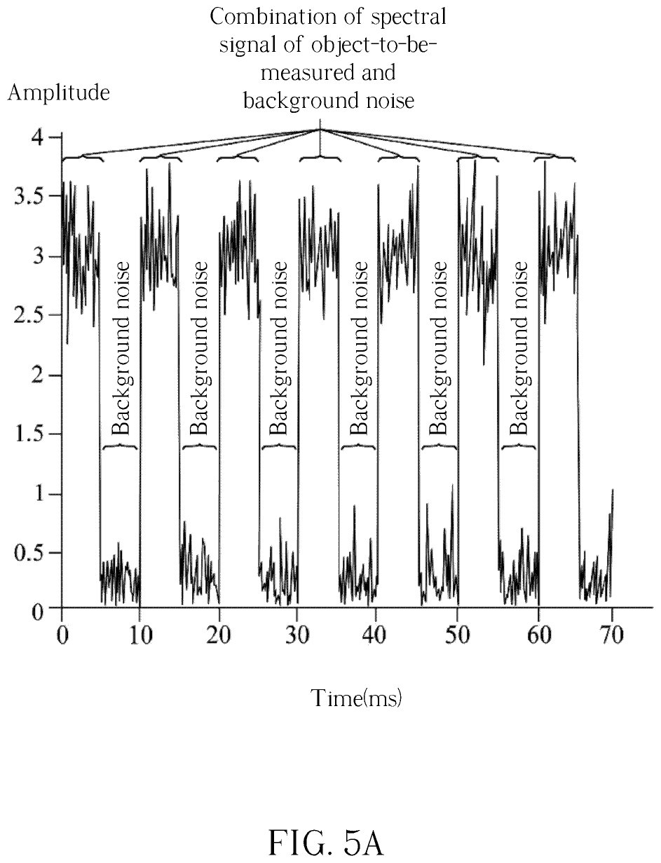

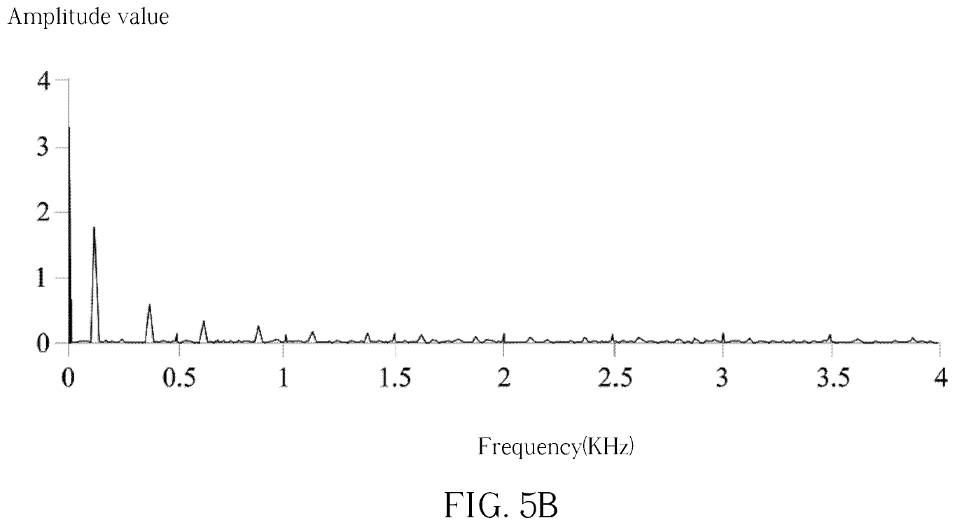

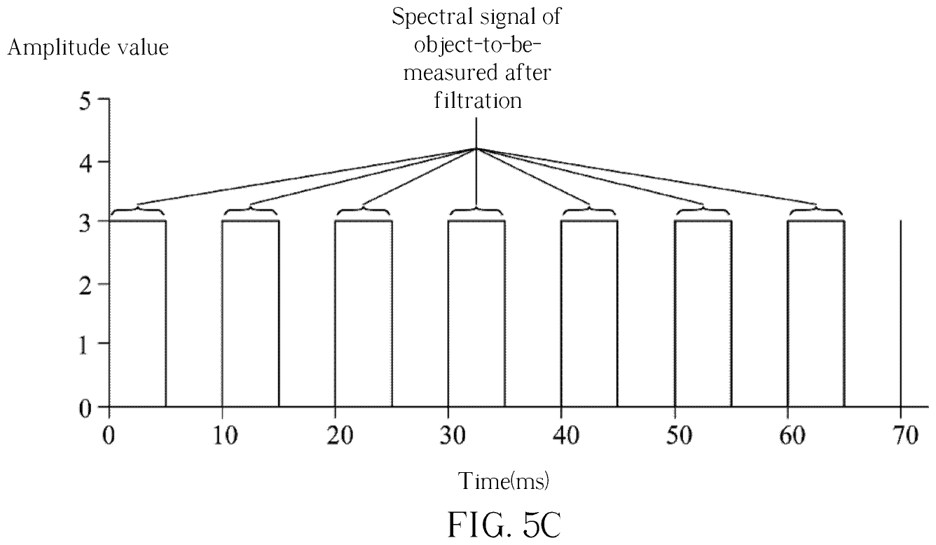

Please refer to FIG. 5A together. It illustrates the discontinuous illumination of the on-off frequency to operate the light detection device (12) to conduct the detection of the object-to-be-measured (A). The spectral signals of object-to-be-measured (A) combines with a background noise and the background noise constitutes a time domain signal of the object-to-be-measured and a time domain signal diagram of the object-to-be-measured. A mathematical analysis module is disposed in the photodetector or in the calculator. The mathematical analysis module is electrically or signally connected to the photodetector, or the mathematical analysis module is electrically or signally connected to the calculator. The mathematical analysis module may be in a form of software or of hardware, and the signals collected by the light detector are transmitted to the mathematical analysis module. When the imaging device is operated to carry out the detection of the object-to-be-measured (A) to generate a spectrum diagram of the object-to-be-measured, a plurality of the light emitting diodes may be turned on or off simultaneously at the same on-off frequency. During the time interval to turn on (light on) the light emitting diode in the on-off frequency, the signals which are received by the photodetector are a combination of the spectral signals of the object-to-be-measured and a background noise (or background sound), and during the time interval to turned off (light off) the light emitting diode of the on-off frequency, the signals which are received by the photodetector are the background noise.

The aforementioned spectral signals of the object-to-be-measured and the background noise which are collected by the light detector are transmitted to the mathematical analysis module. The mathematical analysis module processes the time domain signals of the object-to-be-measured and discards the background noise. For example, the mathematical analysis module includes a time domain frequency domain conversion unit (FIG. 5A) which converts the time domain signals of the object-to-be-measured into frequency domain signals of the object-to-be-measured. The time domain frequency domain conversion unit may be a Fourier transform unit which is for use in undergoing Fourier transformation to convert the time domain signals of the object-to-be-measured into the frequency domain signals of the object-to-be-measured. Please refer to FIG. 5B for the frequency domain signals of the object-to-be-measured and the frequency domain signals diagram of the object-to-be-measured after the transformation. The frequency domain signals of the object-to-be-measured are easily divided into the frequency domain signals of the spectral signals of the object-to-be-measured and the frequency domain signals of the background noise. In FIG. 5B, the frequency domain signals of the peak value at 0 Hz or the frequency domain signals less than the on-off frequency are the frequency domain signals of the background noise; and in FIG. 5B, except the frequency domain signals of the peak value at 0 Hz (i.e. the frequency domain signals of the background noise), the remaining peak signals are the frequency domain signals of the spectral signals of the object-to-be-measured. Preferably, in the frequency domain signals of the object-to-be-measured, a frequency domain signal which is greater than or equal to the on-off frequency is the frequency domain signal of the spectral signal of the object-to-be-measured. The mathematical analysis module discards the frequency domain signals of the background noise to leave the frequency domain signals of the spectrum signals of the object-to-be-measured to achieve the filtering effect. Because the mathematical analysis module discards the frequency domain signals of the background noise, the remaining frequency domain signals of the spectral signals of the object-to-be-measured completely belong to the object-to-be-measured (A) without the inclusion of the background signal. Therefore, compared with the traditional spectrometers, the light detection device (12) of the present invention not only improves the signal-to-noise ratio of object-to-be-measured (A) in the spectrum, the light detection device (12) of the present invention even achieves a spectrum without background noise because the frequency domain signals of the background noise is discarded for filtering. Please refer to FIG. 5A and FIG. 5B again. A microcontroller of the solid-state light source emitter (120) may be electrically or signally connected to the mathematical analysis module to synchronously transmit the on-off frequency, the time interval of turning on (light on) the light emitting diode of the on-off frequency and the time interval of turning off (light off) the light emitting diode of the on-off frequency to the mathematical analysis module, so that the mathematical analysis module can correspond the time interval of turning on (light on) the light emitting diode of the on-off frequency to the spectral signals of the object-to-be-measured, and corresponds the time interval of turning off (light off) the light emitting diode of the on-off frequency to the background noise when the microcontroller turns on or off a plurality of the light emitting diodes which are respectively electrically connected to the microcontroller according to the on-off frequency, the time interval of turning on (light on) the light emitting diode of the on-off frequency and the time interval of turning off (light off) the light emitting diode of the on-off frequency.

To elaborate in particular, the waveform of the discontinuous illumination of the plurality of light emitting diodes which exhibit the on-off frequency is a square wave, a sine wave or a negative sine wave.

In addition, the mathematical analysis module can also process the frequency domain signals of the spectral signals of the object-to-be-measured which are left out after the aforementioned filtering effect, to convert the aforementioned left frequency domain signals of the spectral signals of the object-to-be-measured into the time domain signals of the object-to-be-measured after filtration and a domain signal time diagram of the object-to-be-measured after filtration, wherein there is only spectral signals of the object-to-be-measured after filtration in the time domain signals of the object-to-be-measured after filtration in the absence of the background noise. For example, the mathematical analysis module includes a frequency domain time domain conversion unit (FIG. 5B) which converts the aforementioned left frequency domain signals of the spectral signals of the object-to-be-measured into time domain signals of the object-to-be-measured after filtration (FIG. 5B). The frequency domain time domain conversion unit may be an inverse Fourier transform unit which is used to carry out an inverse Fourier transform on the aforementioned left frequency domain signals of the spectral signals of the object-to-be-measured into the time domain signals of the object-to-be-measured after filtration. Please refer to FIG. 5C for the time domain signals of the object-to-be-measured and the time domain signals diagram of the object-to-be-measured after conversion and filtration. By comparing FIG. 5A and FIG. 5C, it can be clearly observed that only the spectral signals of the object-to-be-measured after filtration exists in the time domain signals of the object-to-be-measured after filtration in the time domain signal diagram of the object-to-be-measured after filtration in FIG. 5C, and in a form of a square wave, and there is no such background noise in the time domain signals diagram of the object-to-be-measured after filtration. In other words, the background signal in FIG. 5C is zero, so the resulting signal-to-noise ratio is infinite if the value of the spectral signals of the object-to-be-measured after filtration is divided by the value of the background signal. Therefore, the present invention improves the signal-to-noise ratio in the spectrum diagram of the test result of the sample (object-to-be-measured) to achieve accurate measurement results. It is particularly noted that the aforementioned mathematical analysis module, the time domain frequency domain conversion unit and the frequency domain time domain conversion unit may be respectively in a form of software or of hardware, or a combination of the aforementioned software form or hardware form. The mathematic analysis module, the time domain frequency domain conversion unit and the frequency domain time domain conversion unit are electrically or signally connected to one another.

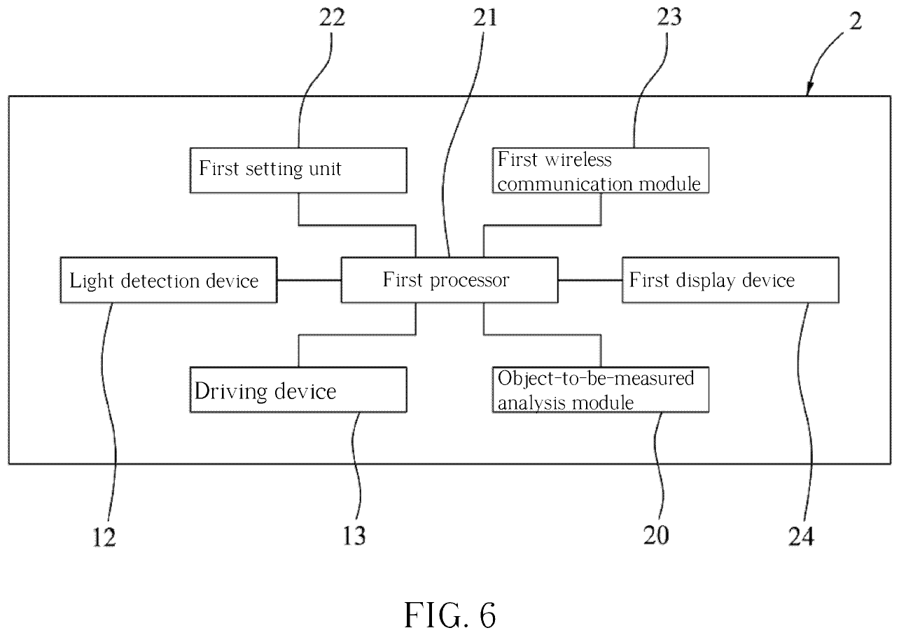

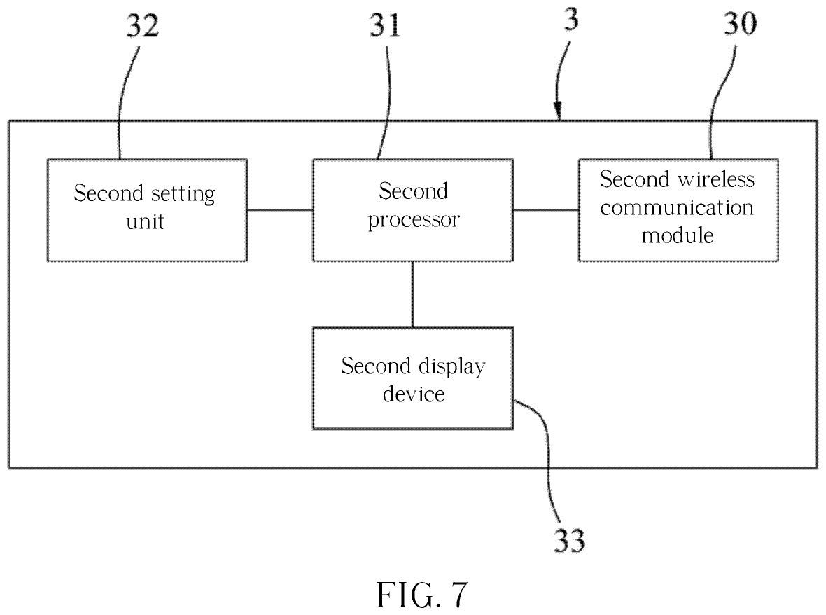

Please refer to FIG. 6 and FIG. 7 together. They are a block diagram of an optical analysis system and a block diagram of electronic equipment of a preferred embodiment of the present invention. The present invention based on the main purpose further provides an optical analysis system suitable for use in the aforementioned optical analyzer (1). The optical analysis system (2) includes a first processor (21) electrically connected to the light detection device (12), the driving device (13), an object-to-be-measured analysis module (20) and a first setting unit (22).

The object-to-be-measured analysis module (20) can analyze the spectrum diagram after the light detection device (12) detects the object-to-be-measured (A), and convert the analysis results into information which a user requires. When applied to a front-loading washing machine (4), the object-to-be-measured analysis module (20) can convert and analyze the obtained spectrum diagram after the clothes are detected by the optical analyzer into various types of information regarding the laundry load prior to the washing of the clothes, for example: the material information of the laundry load, the total content information of the laundry load or the proportion information among different materials of the laundry load to facilitate the subsequent front-loading washing machine to determine the required washing time, the water volume for washing, the content of additives such as laundry detergents or softeners or the number of washes, thereby generating a better washing mode, such as a washing mode which is less harmful to the clothes, a quick washing mode which cleans in shorter time or a full washing mode which fully cleans clothes, etc. To elaborate specifically, if the object-to-be-measured analysis module (20) detects and determines that there is non-clothing information, it generates the information of no mixed load.

In an embodiment of the present invention, the first wireless communication module (23) is communicatively connected to a second wireless communication module (30) of an electronic device (3), and the second wireless communication module (30) is electrically connected to a second processor (31).

For implementation, the optical analyzer (1) can transmit various information and values of the laundry load which are analyzed by the object-to-be-measured analysis module (20) to an electronic device (3) through the first wireless communication module (23) to allow the user to access various information and values of the laundry load at any time through the electronic device (3). Wi-Fi, WiMAX, IEEE 802.11 series, a 4G network, a 5G network, an HSPA network, an LTE network or Bluetooth may be selected for the first wireless communication module (23) and for the second wireless communication module (30).

In an embodiment of the present invention, the optical analysis system (2) further includes a first display device (24). The first display device (24) is electrically connected to the first processor (21). The first display device (24) may display the spectral diagram generated by the light detection device (12) to be converted into the information required by the user, the operating speed or the frequency of the driving device (13). The first display device (24) may be a liquid crystal display.

In an embodiment of the present invention, the optical analysis system (2) further includes a first setting unit (22). The first setting unit (22) for example may be, but not limited to, a touch screen or a button. The first setting unit (22) is electrically connected to the first processor (21). When applied to a front-loading washing machine (4), the first display device (24) may display various information and values of the laundry load prior to the washing of the clothes, and the user may input the desired washing mode, such as a washing mode which is less harmful to the clothes, a quick washing mode which cleans in a shorter time, or a full washing mode which fully cleans the clothes, etc. through the first setting unit (22), or the user may set the washing time, the water volume for washing, the content of additives such as laundry detergents or softeners or the number of washes on their own through the first setting unit (22).

The electronic device (3) may be a personal computer, a personal mobile communication device, a laptop computer or a tablet computer, etc.

In an embodiment of the present invention, the electronic device (3) further includes a second setting unit (32). The second setting unit (32) is electrically connected to the second processor (31). The second setting unit (32), for example may be, but not limited to a touch screen or buttons. The electronic device (3) further includes a second display device (33). The second display device (33) is electrically connected to the second processor (31). The user may access the spectral diagram generated by the light detection device (12) to be converted into the information required by the user, the operating speed or the frequency of the driving device (13) through the electronic device (3), and remotely operate the optical analyzer (1) through the second setting unit (32) and through the second display device (33). When applied to a front-loading washing machine (4), the user may access various information and values of the laundry load through the electronic device (3), and input the desired washing mode through the second setting unit (32), such as: a washing mode which is less harmful to the clothes, a quick washing mode which cleans in shorter time or a full washing mode which fully cleans clothes etc., or the user may set the washing time, the water volume for washing, the content of additives such as laundry detergents or softeners, or the number of washes on their own through the first setting unit (22).

To sum up, compared with the current technologies and products, the present invention has one of the following advantages:

One of the objectives of the present invention is to enable the light detection device to carry out a spectral analysis of the object-to-be-measured in spite of a long distance by using the optical analyzer such as the light emitting diode or the laser diode in the present invention. It is different from the mixed light used by traditional optical analyzers to measure the object-to-be-measured after splitting because the light source used is a simple light source. Therefore, the simple light source used in the present invention has the characteristics of high light source intensity and can not only penetrate a light-transmitting component of glass material but also is there no problem of light source dispersion at different tilt angles to achieve accurate measurement results.
One of the objectives of the present invention is to achieve a measurement method of each piece of clothing of multiple repeated measurements by using a plurality of the light-emitting elements of the present invention which each respectively exhibits discontinuous illumination of an on-off frequency to go with the rotating part to drive the object-to-be-measured holding device to rotate. In addition to being able to measure an object-to-be-measured with a non-planar or a non-stationary surface, it also improves the signal-to-noise ratio in the spectrum diagram after the object-to-be-measured is detected to achieve the results of the accurate measurement.
One of the objectives of the present invention is to apply the structures and operating principles of the optical analyzer of the present invention to various kinds of household or cooking electrical appliances. For example, a front-loading washing machine exemplified in the present invention is one of the specific embodiments. It is able to carry out measurements to obtain spectral data of each pieces of the clothes prior to the washing of the clothes through the optical analyzer of the present invention to further obtain the material information of the laundry load, the total content information of the laundry load or the proportion information among different materials of the laundry load to facilitate the front-loading washing machine to determine the required washing time, the water volume for washing, the content of additives such as laundry detergents or softeners or the number of washes, thereby generating a better washing mode for a user to select.

Any one of the embodiment or the claim of the present invention does not necessarily achieve all the purposes or advantages or features which are disclosed in the present invention. In addition, terms such as “first” and “second” mentioned in this specification or in the claims are only used to name elements or to distinguish between different embodiments or scopes without the intention to limit the upper limit or the lower limit on the number of elements.

Those skilled in the art will readily observe that numerous modifications and alterations of the device and method may be made while retaining the teachings of the invention. Accordingly, the above disclosure should be construed as limited only by the metes and bounds of the appended claims.

1. An optical analyzer, comprising:
a main body having a receiving space, a light-transmitting component provided on one side of the main body, and an object-to-be-measured holding device provided in the receiving space;
a rotating part linked to the object-to-be-measured holding device;
a light detection device having a solid-state light source emitter and an optical receiver, the solid-state light source emitter having a plurality of light-emitting elements, each the light-emitting element emitting a light with at least one peak emission wavelength and at least one wavelength range, the optical receiver receiving a light emitted from the light-emitting element, and the solid-state light source emitter disposed on another side opposite to a side of the receiving space where the light-transmitting component is disposed, wherein the light is able to pass the light-transmitting component and forms an optical path along a travel pathway between the light-emitting element and the optical receiver, a distance between the light emitted from the light-emitting element and an object-to-be-measured in the object-to-be-measured holding device is at least 5 cm, the light-emitting element is a light emitting diode, a vertical-cavity surface-emitting laser or a laser diode, and the plurality of the light-emitting elements respectively exhibit discontinuous illumination of an on-off frequency, a plurality of the on-off frequencies are the same or different from each other, or the plurality of the on-off frequencies are partially the same or partially different; and
a driving device connected to the rotating part;
wherein a time interval of the on-off frequency for turning on the light-emitting element is between 0.00001 seconds and 10 seconds, the on-off frequency is between 0.05 time/second and 50000 times/second, and the time interval of the on-off frequency for turning on the light-emitting element is between 0.00001 seconds and 10 seconds.

2. The optical analyzer as claimed in claim 1, wherein an extension direction of the rotating part is defined as an X direction, the X direction is different from a Y direction and a Z direction, the Y direction and the Z direction define a YZ plane, and the X direction, the Y direction and the Z direction are perpendicular to one another, the object-to-be-measured holding device is able to rotate along the YZ plane, and an angle between a normal line of the YZ plane and the X direction is equal to 0 degree or greater than 0 degree and less than 90 degrees.

3. The optical analyzer as claimed in claim 1, wherein an extension direction of the rotating part is defined as a Z direction, the Z direction is different from an X direction and a Y direction, the X direction and the Y direction define an XY plane, the X direction, the Y direction and the Z direction are perpendicular to one another, the object-to-be-measured holding device is able to rotate along the XY plane, and an angle between a normal line of the XY plane and the Z direction is equal to 0 degree or greater than 0 degree and less than 90 degrees.

4. The optical analyzer as claimed in claim 1, wherein the optical analyzer further includes a reflective element, the reflective element is provided in the object-to-be-measured holding device, and the optical receiver receives the light reflected from the reflective element.

5. The optical analyzer as claimed in claim 1, further comprising:
a mathematical analysis module provided in a photodetector of the optical receiver or in a calculator, wherein the mathematical analysis module is electrically or signally connected to the photodetector or to the calculator, the mathematical analysis module is a software or hardware module, the photodetector transmits at least one signal collected by itself to the mathematical analysis module, and when detection is performed on the object-to-be-measured, a plurality of the light-emitting elements turn on and off at the same on-off frequency at the same time; the time interval of the on-off frequency for turning on the light-emitting element, the signal received by the photodetector is a combination of a spectral signal of the object-to-be measured and a background noise, and a time interval of the on-off frequency for turning off the light-emitting element, the signal received by the photodetector is the background noise; the mathematical analysis module processes the signal received by the photodetector to discard the background noise.

6. The optical analyzer as claimed in claim 1, wherein a difference between adjacent two the peak emission wavelengths is between 1 nm and 80 nm.

7. The optical analyzer as claimed in claim 1, wherein a difference between adjacent two the peak emission wavelengths is between 5 nm and 80 nm.

8. The optical analyzer as claimed in claim 7, wherein a full width at half maximum which each the peak emission wavelength corresponds to is between 15 nm and 50 nm.

9. The optical analyzer as claimed in claim 8, wherein a full width at half maximum which each the peak emission wavelength corresponds to is between 15 nm and 40 nm.

10. The optical analyzer as claimed in claim 1, wherein a plurality of the wavelength ranges of the two light-emitting elements which adjacent two the peak emission wavelengths correspond to partially overlap to form a continuous wavelength range which is wider than the wavelength range of each of the plurality of the light-emitting elements, or the plurality of the wavelength ranges of the two light-emitting elements which adjacent two the peak emission wavelengths correspond to do not overlap.

11. The optical analyzer as claimed in claim 1, wherein a difference between adjacent two the peak emission wavelengths is greater than or equal to 0.5 nm.

12. The optical analyzer as claimed in claim 1, wherein a difference between adjacent two the peak emission wavelengths is between 1 nm and 80 nm.

13. The optical analyzer as claimed in claim 1, wherein a full width at half maximum which at least a portion of the peak emission wavelength in a plurality of peak emission wavelengths corresponds to is greater than 0 nm and less than or equal to 60 nm.

14. The optical analyzer as claimed in claim 1, wherein the light which the light-emitting element emits has an inclination angle with respect to a surface normal line of the light-transmitting component, and the inclination angle is greater than 0 degree and less than 90 degrees.

15. The optical analyzer as claimed in claim 1, wherein a plurality of the light-emitting elements emit light sequentially, and that emit light sequentially refers to a plurality of the light-emitting elements which emit the light of the same wavelength range at different positions do not emit the light at the same time; or the plurality of the light-emitting elements partially emit the light at the same time, that partially emit the light at the same time refers to using the plurality of the light-emitting elements so that a portion of the light-emitting elements emits at the same time and emits the light of different the wavelength ranges at the same time.

16. An optical analysis system, comprising the optical analyzer as claimed in claim 1, further comprising:
a first processor electrically connected to the light detection device, to the driving device, to an object-to-be-measured analysis module and to a first setting unit.

17. The optical analysis system as claimed in claim 16, wherein the optical analysis system further comprising:
a first wireless communication module, and the first wireless communication module electrically connected to the first processor.

18. The optical analysis system as claimed in claim 16, wherein the optical analysis system further comprising:
a first display device, the first display device is electrically connected to the first processor.

19. The optical analysis system as claimed in claim 17, wherein the first wireless communication module is communicatively connected to a second wireless communication module of an electronic device, and the second wireless communication module is electrically connected to a second processor.

20. The optical analysis system as claimed in claim 19, wherein the electronic device further comprises a second setting unit, the second setting unit is electrically connected to the second processor.

21. The optical analysis system as claimed in claim 19, wherein the electronic device further comprises a second display device, the second display device is electrically connected to the second processor.
